(19) United States
(12) Patent Application Publication
(10) Pub. No.: US 2018/0234275 A1
(43) Pub. Date: Aug. 16, 2018

(54) MODULATOR-DEMODULATOR (MODEM) ARCHITECTURE FOR FULL DUPLEX COMMUNCIATIONS

(71) Applicant: Avago Technologies General IP (Singapore) Pte. Ltd., Singapore (SG)

(72) Inventors: Kevin L. Miller, Lawrenceville, GA (US); Thomas J. Kolze, Phoenix, AZ (US)

(73) Assignee: Avago Technologies General IP (Singapore) Pte. Ltd., Singapore (SG)

(21) Appl. No.: 15/896,918

(22) Filed: Feb. 14, 2018

Related U.S. Application Data
(60) Provisional application No. 62/458,857, filed on Feb. 14, 2017.

(51) Int. Cl. H04L 27/10; H04L 5/06

(52) U.S. Cl. CPC H04L 27/10; H03M 1/1205; H04L 5/06

(57) ABSTRACT

Described herein is a modulator-demodulator (modem) that is utilized for improving full duplex communication of a communication system. The modem includes a first digital-to-analog converter (DAC) configured to process data included in a first frequency band (e.g., 5 MHz-85 MHz) and a second DAC configured to process data included in a second frequency band (e.g., 108 MHz to 684 MHz). The modem further includes an uptilt filter configured to tilt a power spectral density of data processed by the second DAC. Moreover, the modem includes a first power amplifier configured to amplify data output by the first DAC, and a second power amplifier configured to amplify data output by the uptilt filter, the first power amplifier operates at a power level lower than a power level of the second power amplifier.

### CROSS-REFERENCE TO RELATED APPLICATION

This application claims the benefit of U.S. Provisional Application No. 62/458,857, filed Feb. 14, 2017, which is herein incorporated by reference in its entirety.

### TECHNICAL FIELD

The present disclosure relates to an improved architecture of a modulator-demodulator (modem) that may be used, for example, in cable communication systems.

### DESCRIPTION OF THE RELATED ART

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Rapid advances in electronics and telecommunication technologies, coupled with the ever increasing demands of consumers, typically direct the evolution of communication systems to move in a direction of reducing the number of hardware components installed in the system. For instance, in cable communication systems, which operate on standards as outlined in the Data Over Cable System Interface Specification (DOCSIS), a primary feature for multiple-channel upstream modems (introduced in version 3.0 of DOCSIS), reflect the beneficial evolution of technology towards implementing a single digital-to-analog converter (DAC) in the upstream modulator.

Due to the signaling and traffic protocols that are widely implemented in support of the current DOCSIS standard (3.1 version) and previous DOCSIS standards, a portion of the upstream transmissions are small grants (i.e., traffic transmission requests), as small as 400 kHz, emancipating from multiple modems. In a developing full duplex operation of such a system there is anticipated a much larger upstream modulated spectrum capability in each modem. One approach for scaling the current DOCSIS 3.1 modem capability to the much larger upstream modulated spectrum involves scaling the bandwidth of the numerous small grants to be proportionally larger, or in other words, the modems would not support the small bandwidth transmissions of the current DOCSIS standards. This leads to an inefficient use of the frequency spectrum and degradation of system performance. Another alternative is to support the current size of the small bandwidth transmissions in the full duplex system, therefore accommodating a significant increase in the ratio of the largest supported upstream transmission bandwidth to the current smallest supported upstream transmission bandwidth, but increasing this ratio generally causes a significant increase in the modem complexity.

Accordingly, an enhanced modem architecture that achieves improved full duplex system performance, while minimally affecting the complexity of the communication system is required.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is an exemplary schematic diagram of a cable modem communication system; and

FIG. 2 is an exemplary block diagram of a modem, by one embodiment.

### DETAILED DESCRIPTION

The present disclosure provides for an enhanced modem architecture that aims at separating a first frequency band, and a second frequency band into two separately controlled entities for full duplex (FDX) operation. For instance, considering a cable modem communication system, the enhanced modem architecture of the present disclosure leverages the currently used upstream frequency spectrum (as governed by DOCSIS standard) by separating a portion of the legacy spectrum (e.g., 5 MHz-85 MHz) from the anticipated full-duplex spectrum (e.g., 108 MHz-684 MHz). By one embodiment, the enhanced modem architecture utilizes a lower powered and smaller modulated portion of the spectrum (e.g., 5 MHz-85 MHz) for transmitting substantially all of the smaller grants, and also some larger grants, while only using a subset of current DOCSIS upstream signal levels, as one part of a combined FDX solution, to minimize risk and complexity, as well as reducing the amount of DOCSIS higher layer functions which need to be adapted for FDX. The higher frequency spectrum in the FDX solution (e.g., 108 MHz to 684 MHz), will generally not be used for the smaller grants.

It must be appreciated that the architecture of the modem as described herein is in no way restricted to be used only in a cable communication system. Rather, the present modem architecture can be deployed in a wide range of emerging networking technologies (e.g., high speed data networks, passive optical networks, mobile networks, and the like), especially in cases where high data rates of communication are requested/demanded, while ensuring that higher layered applications that rely on communicating smaller data packets (e.g., acknowledgement packets) also operate efficiently. Furthermore, the architecture of the modem presented herein is in no way limited to be used with a particular modulation scheme and/or error coding technique. For sake of simplicity, and with an aim to highlight the various advantages provided by the architecture of the modem, a cable communication system is used as example in the following discussion.

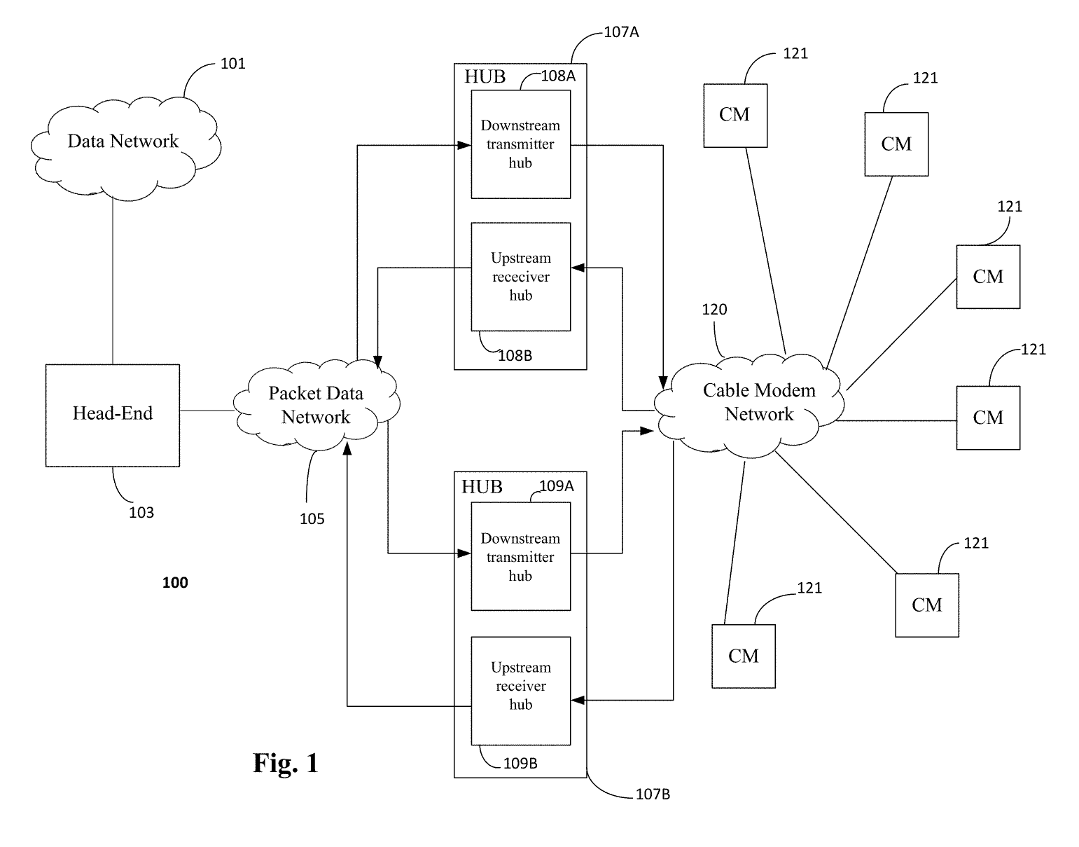

Turning to FIG. 1, there is provided an exemplary cable modem communication system 100. The cable modem communication system 100 includes a distributed Cable modem Termination System (CMTS). Specifically, as illustrated in FIG. 1, the distributed CMTS includes a head end 103, and distributed hubs 107A and 107B. By one embodiment, each of the distributed hubs 107A and 107B may be envisioned to service a respective Data Over Cable System Interface Specification (DOCSIS) Physical Layer (PHY) domain. Each DOCSIS PHY domain 107A and 107B services a plurality of cable modems (CMs) 121. The head end 103 couples to the hubs 107A and 107B via a packet data network 105. The head end 103 transfers data to, and receives data from the cable modems 121 via the hubs 107A and 109A, and the packet data network 105.

It must be appreciated that the cable modem communication system 100 may include more than two hubs, each of which is communicatively coupled to the packet data network 105 on one side, and a cable modem network 120 on the other side. However, for sake of convenience only two hubs 107A and 107B are depicted in FIG. 1.

Each of the hubs 107A and 107B include a downstream transmitter hub (108A and 109A, respectively), and an upstream receiver hub (108B and 109B, respectively). The head end 103, the downstream transmitter hubs 108A and 109A, and the upstream receiver hubs 108B and 109B, couple to one another via the packet data network 105. The packet data network 105 may be an Ethernet network or another type of packet data network. The downstream transmitter hubs 108A and 109A, and the upstream receiver hubs 108B and 109B may reside in differing facilities. However, in other embodiments the downstream transmitter hubs and the upstream receiver hubs may be located in a single facility. For example, it should be appreciated that the cable modem communication system 100 may have a Remote PHY architecture wherein the hubs 107A and 107B which contain the downstream modulator and the upstream receiver may be commonly referred to as nodes or Remote PHY Devices. It will be clear to those skilled in the art that these differences within the cable modem communication system 100 are not limiting of the benefit of practicing the invention disclosed here.

The downstream transmitter hubs and the upstream receiver hubs couple to the cable modem network 120. As shown in FIG. 1, each of the CMs 121 also couples to the cable modem network 120. The cable modem network 120 may be a hybrid fiber coaxial (HFC) cable modem network, or another type of cable modem network plant that's generally known. The distributed CMTS services data communications between data network 101 and CMs 110 via the cable modem network 120. By one embodiment, the cable modem network 120 uses a tree-and-branch architecture with analog transmission, and includes the following key functional characteristics: (a) two-way transmission; and (b) a maximum optical/electrical spacing between the CMTS and the most distant CM of 100 miles (160 km) in each direction, although a practical maximum separation may be in the order of 10-15 miles (16-24 km).

In what follows, there is provided a description of a novel upstream transmitter to be used in conjunction with a network communication system. For sake of simplicity, hereinafter a cable modem communication system is considered, and the upstream transmitter is referred to as a Cable modem (CM) upstream transmitter or simply a modem.

According to an aspect of the present disclosure, there is provided an innovative Cable modem (CM) upstream transmitter for a new generation of cable system. The CM incorporates both upstream and downstream transmissions in the frequency band, e.g., 108 MHz to 684 MHz. The architecture of the CM described herein provides at least the following advantageous abilities: (a) availability of high fidelity requirements with tilted (i.e., not flat) signal power spectral density (PSD) in one portion of the upstream band, while maintaining nominally flat signal PSD in another portion of the upstream band (tilting only the higher frequency band is a favored embodiment for minimal complexity, however the other aspects of the invention are not dependent upon this); (b) the use of separate Dynamic Range Windows (DRW), and control of the respective windows in the respective two upstream bands (a single DRW may be used in conjunction with this invention, but separate DRWs allow more flexibility in optimizing the system throughput for a particular HFC plant); (c) accommodating small grants in only one portion of the upstream band, while directing large grants to either portion of the upstream band.

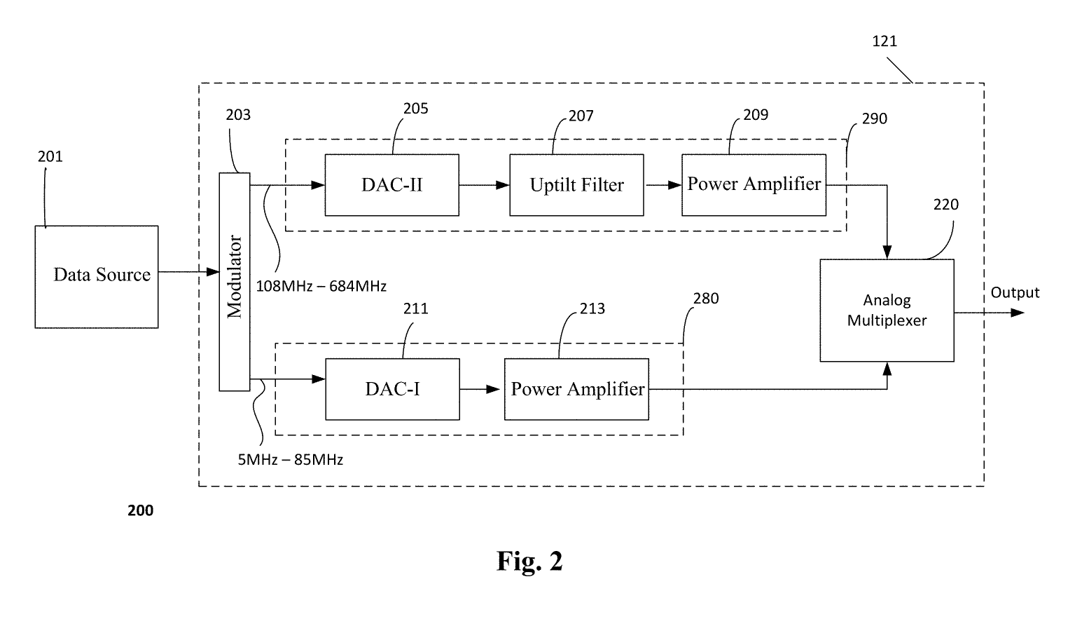

Turning to FIG. 2 is illustrated an exemplary block diagram 200 of a modem according to one embodiment of the present disclosure. As shown in FIG. 2, a data source 201 feeds data to a modulator 203 of the modem 121. The modem 121, in a full duplex operation mode, separates the upstream frequencies into two separate bands: a first band of, e.g., 5 MHz-85 MHz, and a second band of, e.g., 108 MHz-684 MHz, respectively. As shown in FIG. 2, the first band of frequencies is processed by block 280, whereas the second band of frequencies is processed by block 290. In other words, block 280 is a first transmit channel and block 290 is a second transmit channel. In a general case, grants may be in the first frequency channel and the second frequency channel. Some grants may transmit for an extended period of time, while other grants may transmit for a shorter period of time. While the longer grant is transmitted, another grant may arrive. This upstream traffic is managed by the CMTS using various algorithms and service flows for scheduling. From a hardware perspective of the modulator 203, the CMTS directs the cable modem to send a particular data source's data at a particular time in a predetermined portion of the frequency band. As a result, multiple specific grants are handed out to a cable modem covering a period of time. This includes requests for more grants, and then the CMTS looks at all the requests from all the cable modems and parcel out another set of grants for each cable modem covering another period of time. Generally, the CMTS does the scheduling and the cable modem responds as described in DOCSIS.

A benefit of splitting the first band of frequencies into block 280 and a second band of frequencies into block 290 can be explained in the following example. A 100% grant can be received at a particular point in time, and several microseconds later, a small grant can be received. In the prior DOCSIS 3.1, the upstream band was 5 MHz-204 MHz, and a 190 MHz of modulated spectrum could be received, and a few microseconds later, 400 kHz of modulated spectrum, and the 190 MHz modulated spectrum and the 400 kHz modulated spectrum could have had the same power spectral density. This creates a significant drop in power from microsecond to microsecond. In other words, the modem 121 may have to handle the smallest grant next to the largest grant in the time domain with the same power spectral density. As a result, for example, the modem 121 needs to be able to handle a 30+ dB instantaneous change in power (when additionally considering that the PSD of the 400 kHz grant could be 3 dB or more lower than the PSD of the 190 MHz grant) which requires significant fidelity requirements to be met to tolerate that change. To handle this, using two separate frequency bands with separate DACs can maintain fidelity to meet the specifications for transmission characteristics in DOCSIS. Therefore, the grants can be independent between the first band of frequencies and the second band of frequencies while the second band of frequencies can have a minimum grant bandwidth as further described herein.

The first band of frequencies is processed initially by a digital-to-analog converter 211, whereafter the analog signal is passed through a power amplifier that operates at, e.g., 55 dBmV. The second band of frequencies is processed by a second digital-to-analog converter 205, whereafter the analog signal is processed by an uptilt filter 207. The uptilt of the PSD may be accomplished in a multiplicity of ways any of which do not mitigate the advantages of practicing this invention. One method is to provide the uptilt digitally, prior to Digital to Analog Conversion (DAC), which in itself further increases the difficulty of maintaining fidelity in the DAC and digital processing preceding the DAC. This approach carries the difficulty of meeting the noise floor requirements (a portion of the fidelity requirements) at the lower frequencies due to the lower signal level from the DAC and into the power amplifier at the lower frequencies. Another possibility is to provide an analog uptilt filter after power amplification, but this is accomplished with significant insertion loss at the lower end of the frequency range, which is inefficient use of the power amplifier. Another possibility is to provide post-DAC, but prior to power amplification, an analog uptilt filter, which would have more insertion loss at the lower frequencies. This approach avoids the inefficient use of the post-power-amp filter, but may still result in difficulties with the noise floor (a factor in meeting the fidelity requirements). Another possibility is to provide the uptilt by using a tilted response filter in the feedback network of the power amplifier which will serve to provide a higher gain at higher frequencies and a lower gain at the lower frequencies. Any of these embodiments are feasible and are accompanied with different tradeoffs, but practicing the invention is beneficial in all these embodiments of the uptilt filtering. The invention is beneficial even without the necessity of practicing uptilt filtering in either or both channels, or flat or downtilt filtering in any channel, for that matter. More easily providing the flat nominal PSD of the first frequency channel and the nominal uptilt PSD of the second frequency channel is an additional benefit of practicing the invention. As another note on the power amplification circuits in FIG. 2, it is not impactful on the advantages of the invention if the power amplifier for the first frequency channel is integrated into the DAC circuit. The same is true for the second frequency channel as well. The uptilt filter 207 is configured to tilt the PSD of the incoming analog signal. Upon tilting the PSD of the analog signal, the analog signal is processed by a power amplifier 209, which operates at, e.g., 65 dBmV. The outputs of the two power amplifiers 213 and 209 are combined by an analog multiplexer 220. Note that the analog multiplexer 220 provides a low-insertion loss method of combining the two signal streams. Other methods of combining the two frequency channels may be practiced, and these do not impact the advantages of the invention. The output of the analog multiplexer 220 is shown as the upstream output of the modem 121, but in the DOCSIS CMs the downstream modem input and upstream modem output share a common interface; the circuits associated with the combining and separating of the downstream signals within the modem are not illustrated in the figure. Furthermore, it must be appreciated that several other modems may be combined via taps, which are a part of any cable plant or HFC network. Note that the architecture as shown in FIG. 2 separates the processing of the first frequency band from the second frequency band. Doing so, provisions the modem so small grants use the first band, and moreover implements the tilting of the PSDs only for a portion of the upstream frequency spectrum (e.g., 108 MHz-684 MHz).

Described next are the advantages incurred by using the architecture of the modem as described with reference to FIG. 2. Specifically, the advantages incurred while implementing the modem in a full-duplex (FDX) mode of operation, while maintaining the compatibility requirements with a communication standard such as DOCSIS 3.1 are described. The efficient management of upstream overall link budgets with a multiplicity of CMs capable of (and granted) upstream burst transmissions simultaneously is incorporated as an aspect of the architecture (FIG. 2), and envisioned method of system operation and management, with low risk based on DOCSIS 3.1 and earlier standards, but including changes necessitated by the new requirements of DOCSIS-full duplex mode of operation, while maintaining a minimal possible complexity are described.

By one embodiment, a key feature of the modem architecture of the present disclosure is the separating of the, e.g., 5 MHz-85 MHz band, and the, e.g., 108 MHz-684 MHz band, into two separately controlled Dynamic Range Window groups and two separately controlled Transmit Channel Set groups, for FDX operation. Many advantages are obtained by an embodiment operating with a single DRW, so operation with two or more DRWs is not necessary to practice the invention beneficially. However, operating two Transmit Channel Set groups, instead of a single homogeneous Transmit Channel Set as in prior DOCSIS, provides many advantages, although seemingly moves against the direction of technology (and even the DOCSIS standards over the past twenty years). It must be appreciated that the modem architecture would still provide support of DOCSIS 3.1 standard operation in 5 MHz to possibly 204 MHz for backward compatibility, if operating with a D3.1 CMTS, for example, and thus not operating in an FDX mode. Further, as described with reference to FIG. 2, by one aspect of the present disclosure, a first frequency band in the FDX operation is suggested with a maximum of only, e.g., 55 dBmV power requirement, while the second frequency band would have a maximum of, e.g., 65 dBmV total average power, and further accommodate tilt.

In the following, there is provided a description of the required changes to be made in the PHY specification for DOCSIS 3.1, which are necessitated due to the improved architecture of the modem as described with reference to FIG. 2. It must be appreciated that the new architecture of the modem enables efficient upstream communication, leverages previous DOCSIS requirements and re-use of system operations and management, with a key simplification being introduced: implementing two DACs, one for each of the first band, and the second band. Further, small grants are provisioned only in the first band, whereas large grants are directed to either band.

By one embodiment, the modem architecture of the present disclosure utilizes two DACs (and in general, a multiplicity of DACS), and up to six OFDMA channels in the second frequency band. In the DOCSIS 3.1 standard, a functionality called maximum scheduled mini-slots operates such that the CMTS limits the number of mini-slots concurrently scheduled to the CM, such that the CM is not given transmit opportunities on that OFDMA channel that will result in overreaching its reported transmission power capability. By introducing the new modem architecture that separates the upstream frequency spectrum into (perhaps) two separately controlled Dynamic Range Window groups and two (or in general, more) Transmit Channel Set groups, the maximum scheduled mini-slot functionality may be avoided in the second frequency band, or perhaps even both frequency bands, thereby providing a reduction in processing complexity of the system. Moreover, the new modem architecture modifies the maximum supported power spectral density (PSD). Specifically, the parameter P_{1.6hi} that is defined in the standard as the maximum equivalent channel power which applies to each of the channels in the TCS is lowered, providing a reduction in the modem complexity. Furthermore, the additional 9 dB range of power (reduction of power compared to normal data transmissions) that is required for initial ranging purposes can be eliminated in the second frequency band, reducing the complexity of the FDX modem.

Additionally, it must be noted that currently limitations will be imposed on the grant size in the second spectrum band, and also on the number of simultaneous CMs which can transmit upstream (e.g., from 40 down to 7), to avoid a significant increase in modem complexity compared to D3.1 PHY modems, as evident from the DOCSIS 3.1 PHY specification. The limitations get more restrictive if the first band is included in the same Transmit Channel Set. Thus, separating the two bands of frequencies eases the grant restriction in the new FDX upstream band, eliminates any further grant restriction in the first band from where current requirements stand, and allows tilt to be included in the control of the DRW PSD without changing the current practice in the first band (requirements based on flat signal PSD), and separates the higher spurious emissions PSD for the FDX band from also causing the detrimental increase in the first band compared to current DOCSIS 3.1 requirements. The new architecture keeps many critical requirements unchanged (or eased, such as lower power) in the legacy band, the first band, and thereby provides the same functionality to the MAC and higher layers, minimizing risk and complexity in system operation in moving toward capable of full duplex operation. These are significant advantages, and are provided while the FDX system and modem provide much higher data rate with the vastly increased upstream spectrum, while maintaining system operation in the legacy first band rather than incurring significant restrictions in this band due to the addition of the second band.

It is to be appreciated that while the two frequency bands can have separate DRW management, it is important for a CMTS controller to keep the signal PSD close at the lower end of the second band to the signal PSD as the upper end of the first band in order to keep the spurious emissions from one band impacting the other too much. For instance, the modem architecture of FIG. 2 provisions: for small grants at 5% with 190 MHz TCS, the spurious emissions floor to be at −57 dBc, and for small grants at 2.5% with 95 MHz TCS down to 24 MHz TCS, the spurious emissions floor to be −60 dBc. Moreover, an extended full duplex TCS of 570 MHz (6 channels×95 MHz=570) yields grant floor being reached at 15%, wherein small grant spurious emissions floor is at −52 dBr.

The separation of the first (lower frequency) band from the second band in a processing chain also allows simplification in providing isolation from even intermodulation products arising in the generation of the signal in the second band, such as in a DAC and amplifier(s), from falling back into the spectrum occupied by the first frequency band, so that the achievement of a given spurious emissions floor in the first band will be easier with the separation. The presence of uptilt in the second band makes the achievement of a given spurious emissions floor in the first band even more difficult without the separation, so in the presence of uptilt in the second band, offering another advantage of the separation.

By one embodiment, the modem of FIG. 2 includes one or more processing circuits that are configured to carry out desired functionality of the modem. The modem may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)) that carry out the functions described above. Further, the modem may include at least one computer readable medium or memory for holding instructions programmed according to any of the teachings of the present disclosure and for containing data structures, tables, records, or other data described herein. The term “computer readable medium” as used herein refers to any non-transitory medium that participates in providing instructions to the processor for execution. A computer readable medium may take many forms, including but not limited to, non-volatile media or volatile media. Non-volatile media includes, for example, optical, magnetic disks, and magneto-optical disks, such as the hard disk or the removable media drive. While aspects of the present disclosure have been described in conjunction with the specific embodiments thereof that are proposed as examples, alternatives, modifications, and variations to the examples may be made.

1. An apparatus comprising:
a first digital-to-analog converter (DAC) configured to process data included in a first frequency band;
a second DAC configured to process data included in a second frequency band;
a first amplifier configured to amplify an output of the first DAC;
a second amplifier configured to amplify an output of the second DAC; and
a multiplexer configured to combine outputs of the first and the second amplifiers.

2. The apparatus of claim 1, wherein the second frequency band is non-overlapping with the first frequency band.

3. The apparatus of claim 2, wherein the first frequency band includes frequencies in the range 5 MHz-85 MHz, and the second frequency band includes frequencies in the range 108 MHz to 684 MHz.

4. The apparatus of claim 1, further comprising an uptilt filter configured to filter the output of the second DAC prior to providing the output of the second DAC to the second amplifier,
wherein the uptilt filter is configured to tilt a power spectral density of data processed by the second DAC.

5. The apparatus of claim 1, wherein the first amplifier operates at a power level lower than a power level of the second amplifier.

6. The apparatus of claim 1, wherein small grants are provisioned only in the first DAC and large grants, larger than the small grants, are directed to the first or second DAC.

7. The apparatus of claim 6, wherein the second DAC is configured to only receive grants with at least a predetermined minimum grant bandwidth.

8. A modem, comprising:
processing circuitry configured to
receive grants from a data source, and
separate the grants into a first frequency band and a second frequency band;
a first digital-to-analog converter (DAC) configured to process data included in the first frequency band; and
a second DAC configured to process data included in the second frequency band.

9. The modem of claim 8, wherein the second frequency band is non-overlapping with the first frequency band.

10. The modem of claim 9, wherein the first frequency band includes frequencies in the range 5 MHz-85 MHz, and the second frequency band includes frequencies in the range 108 MHz to 684 MHz.

11. The modem of claim 8, further comprising:
a first amplifier configured to amplify an output of the first DAC;
a second amplifier configured to amplify an output of the second DAC; and
a multiplexer configured to combine outputs of the first and the second amplifiers.

12. The modem of claim 11, further comprising an uptilt filter configured to filter the output of the second DAC prior to providing the output of the second DAC to the second amplifier,
wherein the uptilt filter is configured to tilt a power spectral density of data processed by the second DAC.

13. The modem of claim 12, wherein the first amplifier operates at a power level lower than a power level of the second amplifier.

14. The modem of claim 8, wherein small grants are provisioned only in the first DAC and large grants, larger than the small grants, are directed to the first or second DAC.

15. The modem of claim 14, wherein the second DAC is configured to only receive grants with at least a predetermined minimum grant bandwidth.

16-20. (canceled)

21. A method, comprising:
receiving, via a modulator, grants from a data source,
separating, via the modulator, the grants into a first frequency band and a second frequency band,
wherein a first digital-to-analog converter (DAC) is configured to process data included in the first frequency band,
wherein a second DAC is configured to process data included in the second frequency band,
wherein a first amplifier is configured to amplify data output by the first DAC, and a second amplifier is configured to amplify data output by the second DAC,
wherein a multiplexer is configured to combine outputs of the first and the second amplifiers, and
wherein the second frequency band is non-overlapping with the first frequency band.

22. The method of claim 21, wherein the first frequency band includes frequencies in the range 5 MHz-85 MHz, and the second frequency band includes frequencies in the range 108 MHz to 684 MHz.

23. The method of claim 21, wherein an uptilt filter is configured to filter the output of the second DAC prior to providing the output of the second DAC to the second amplifier,
wherein the uptilt filter is configured to tilt a power spectral density of data processed by the second DAC, and
wherein the first amplifier operates at a power level lower than a power level of the second amplifier.

24. The method of claim 21, wherein small grants are provisioned only in the first DAC and large grants, larger than the small grants, are directed to the first or second DAC.

25. The method of claim 22, wherein the second DAC is configured to only receive grants with at least a predetermined minimum grant bandwidth.
